(19) United States
(12) Patent Application Publication
(10) Pub. No.: US 2008/0042177 A1
(43) Pub. Date: Feb. 21, 2008

(54) Image sensor and method of fabricating the same

(75) Inventor: Wonje Park, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/812,436

(22) Filed: Jun. 19, 2007

(30) Foreign Application Priority Data
Aug. 16, 2006 (KR) 10-2006-0077246

(51) Int. Cl. H01L 31/0232; H01L 31/18

(52) U.S. Cl. 257/294; 438/69; 257/E31.125; 257/E31.128; 257/E21.579; 257/E21.58

(57) ABSTRACT

In one embodiment, the method includes forming a first dielectric layer over a substrate, and removing a portion of the first dielectric layer over a photoactive region of the substrate to form a concavity in the first dielectric layer. An inner lens and etch stop layer are formed over the substrate simultaneously. The inner lens fills the concavity in the first dielectric layer, and the etch stop layer covers the inner lens and extends over the first dielectric layer. A second dielectric layer may be formed over the inner lens and the etch stop layer. The second dielectric layer may be formed of a different material than the etch stop layer. A cavity may be formed in the second dielectric layer over the inner lens.

### BACKGROUND OF THE INVENTION

1. Field of the Invention

The present invention relates to CMOS image sensors.

2. Description of Related Art

Semiconductor image sensing devices are widely used for capturing images in a variety of applications such as digital cameras, camcorders, printers, scanners, etc. The semiconductor image sensing devices include image sensors that capture optical information and convert the optical information into electrical signals. The electrical signals are processed, stored and otherwise manipulated to produce an image on a display or medium (e.g., print medium).

Two types of semiconductor image devices are currently in wide use: a charge coupled device (CCD) and a CMOS image sensor. A CMOS image sensor operates with lower power consumption than a CCD, and therefore, finds particular applicability to portable electronic devices. A CMOS image sensor or sensing system typically includes a CIS unit and an image signal processing (ISP) unit. The CIS unit performs the function of converting optical information into electrical information, and the ISP unit performs the function of signal processing the electrical information. More particularly, the CIS unit includes an array of pixels formed by photocells and associated digital coding circuitry. Each photocell includes a photodiode to sense illumination, and convert optical information into an analog voltage level. The digital coding circuitry converts the analog voltage level into a corresponding digital code through correlated double sampling (CDS). The digital codes are supplied to the ISP unit, which performs the signal processing function on the received digital codes. The CIS unit and ISP unit may be on a single chip or on separate chips.

As will be appreciated, the applications for such image sensors have increasingly demanded reductions in size and cost as well as improvement in pixel count and performance. However, reductions in size and/or increase in pixel count make increased performance more difficult. For example, optical cross talk becomes a greater problem. Optical cross talk results when light for a pixel is received at a neighboring pixel.

### SUMMARY OF THE INVENTION

The present invention relates to a method of forming an image sensor.

In one embodiment, the method includes forming a first dielectric layer over a substrate, and removing a portion of the first dielectric layer over a photoactive region of the substrate to form a concavity in the first dielectric layer. An inner lens and etch stop layer are formed over the substrate simultaneously. The inner lens fills the concavity in the first dielectric layer, and the etch stop layer covers the inner lens and extends over the first dielectric layer. A second dielectric layer may be formed over the inner lens and the etch stop layer. The second dielectric layer may be formed of a different material than the etch stop layer. A cavity may be formed in the second dielectric layer over the inner lens.

In one embodiment, the cavity is formed using an etchant that has etch selectivity between the second dielectric layer and the etch stop layer.

In one embodiment, the method further includes forming a planarization layer over the substrate that fills the cavity, and forming a micro lens over the planarization layer and the cavity.

In one embodiment, the inner lens and the etch stop layer may be formed of SiN, and the second dielectric layer may be SiO₂.

In one embodiment, the first dielectric is formed as part of a damascene process to form a metal interconnect. For example, the metal interconnect may include copper.

In one embodiment, the second dielectric is formed as part of a damascene process to form a metal interconnect. For example, the metal interconnect may include copper.

In an embodiment, the inner lens has a higher refractive index than the first dielectric layer.

Another embodiment of forming an image sensor includes forming an interlayer dielectric layer over a substrate such that the interlayer dielectric layer is formed over a photoactive region of the substrate. An etch mask is formed over the interlayer dielectric layer, and the etch mask exposes a portion of the interlayer dielectric over the photoactive region. The interlayer dielectric layer is isotropically etched using the etch mask. After removing the etch mask, an inner lens and etch stop layer are formed over the substrate simultaneously. The inner lens fills a concavity in the interlayer dielectric layer created by the isotropically etching, and the etch stop layer covers the inner lens and extends over the interlayer dielectric layer. A first damascene process is performed to form a metal interconnect over the substrate. The first damascene process forms an inter-metal dielectric layer over the inner lens and the etch stop layer. Here, the inter-metal dielectric layer is formed of a different material than the etch stop layer. A cavity is formed in the inter-metal dielectric layer over the inner lens by etching using an etchant that has etch selectivity between the inter-metal dielectric layer and the etch stop layer. A planarization layer is formed over the substrate and fills the cavity. A micro lens is formed over the planarization layer and the cavity.

Yet another embodiment of the method includes forming an interlayer dielectric layer over a substrate such that the interlayer dielectric is formed over a photoactive region of the substrate. A damascene process is performed to form a first metal interconnect over the substrate. The damascene process forms a first inter-metal dielectric layer over the photoactive region of the substrate. An etch mask is formed over the first inter-metal dielectric layer, and the etch mask exposes a portion of the first inter-metal dielectric over the photoactive region. The first inter-metal dielectric layer is isotropically etched using the etch mask. After removing the etch mask, an inner lens and etch stop layer are formed over the substrate simultaneously. The inner lens fills a concavity in the first inter-metal dielectric layer created by the isotropically etching, and the etch stop layer covers the inner lens and extends over the first inter-metal dielectric layer. A damascene process is performed to form a second metal interconnect over the substrate. The damascene process forms a second inter-metal dielectric layer over the inner lens and the etch stop layer. The second inter-metal dielectric layer is formed of a different material than the etch stop layer and the inter-metal dielectric layer. A cavity is formed in the second inter-metal dielectric layer over the inner lens by etching using an etchant that has etch selectivity between the second inter-metal dielectric layer and the etch stop layer. A planarization layer is formed over the substrate and fills the cavity. A micro lens is formed over the planarization layer and the cavity.

The present invention also relates to an image sensor.

In one embodiment, the image sensor includes a substrate having a photoactive region formed therein, and a dielectric layer formed over the substrate. The dielectric layer has a concave portion in an upper surface, and the concave portion is disposed over the photoactive region. An inner lens layer fills the concave portion of the dielectric layer and extends over the dielectric layer. At least one interconnect structure includes a plurality of layers formed over at least a portion of the inner lens layer which extends over the dielectric layer, and at least one of the plurality of layers defines a cavity over the inner lens layer. At least one of the plurality of layers forms a first metal interconnect. The image sensor further includes a planarization layer formed over the substrate and filling the cavity. A micro lens is formed over the planarization layer and over the photoactive region.

### BRIEF DESCRIPTION OF THE DRAWINGS

The present invention will become more fully understood from the detailed description given herein below and the accompanying drawings which are given by way of illustration only, wherein like reference numerals designate corresponding parts in the various drawings, and wherein:

FIGS. 1-8 are schematic cross-sectional views of an image sensor during various stages of a fabrication process according to an embodiment of the present invention.

FIGS. 9-17 are schematic cross-sectional views of an image sensor during various stages of a fabrication process according to an embodiment of the present invention.

FIG. 18 illustrates a further embodiment of an image sensor.

### DETAILED DESCRIPTION OF EXAMPLE EMBODIMENTS

Example embodiments will now be described more fully with reference to the accompanying drawings. However, example embodiments may be embodied in many different forms and should not be construed as being limited to the example embodiments set forth herein. Example embodiments are provided so that this disclosure will be thorough, and will fully convey the scope to those who are skilled in the art. In some example embodiments, well-known processes, well-known device structures, and well-known technologies are not described in detail to avoid the unclear interpretation of the example embodiments. Throughout the specification, like reference numerals in the drawings denote like elements.

It will be understood that when an element or layer is referred to as being “on”, “connected to” or “coupled to” another element or layer, it may be directly on, connected or coupled to the other element or layer, or intervening elements or layers may be present. In contrast, when an element is referred to as being “directly on,” “directly connected to” or “directly coupled to” another element or layer, there may be no intervening elements or layers present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Thus, a first element, component, region, layer or section discussed below could be termed a second element, component, region, layer or section without departing from the teachings of the example embodiments.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a”, “an” and “the” may be intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments may be described herein with reference to cross-section illustrations that may be schematic illustrations of idealized embodiments (and intermediate structures). As such, variations from the shapes of the illustrations as a result, for example, of manufacturing techniques and/or tolerances, are to be expected. Thus, the example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to limit the example embodiments.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

A method of forming an image sensor according to a first embodiment will be described. Then, other embodiments of the present invention will be similarly described.

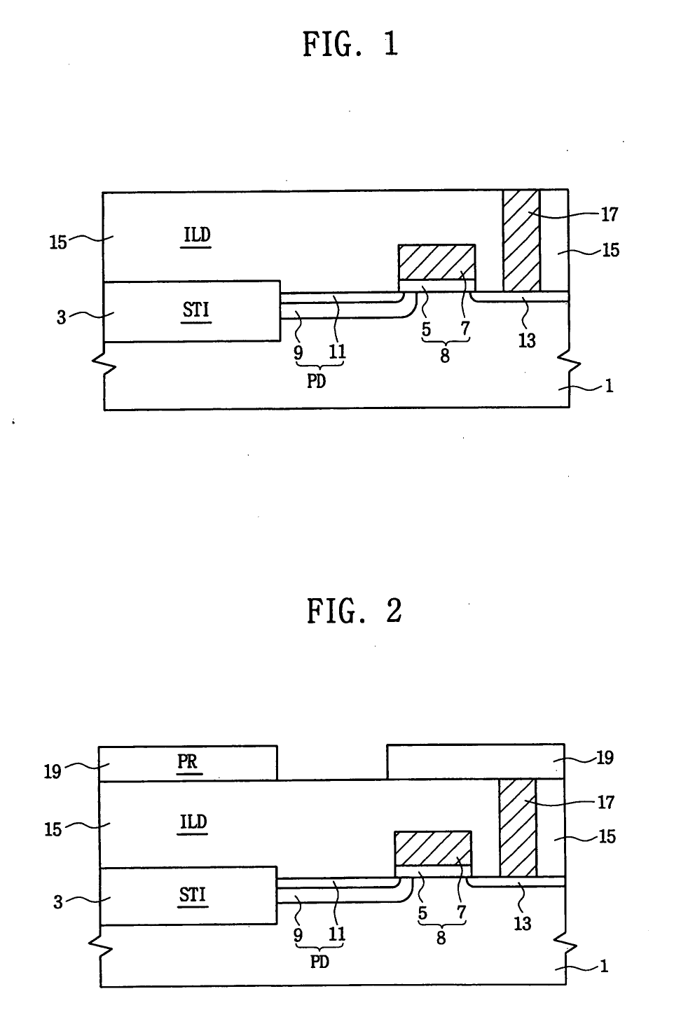

FIGS. 1-8 are schematic cross-sectional views of an image sensor during various stages of a fabrication process according to an embodiment of the present invention. As shown in FIG. 1, a shallow trench isolation region 3 is formed in a substrate 1 (e.g., a silicon (Si) substrate) to isolate active regions of the substrate 1. A gate structure 8 is formed over the active region, and includes a gate insulator 5 (e.g., formed of silicon dioxide (SiO₂)) and a conductive gate 7. The conductive gate 7 may be formed of polysilicon. The patterning process used to form the gate structure is well-known and will not be described in detail. A doping operation takes place to form a photodiode PD in the semiconductor substrate 1 on one side of the gate structure 8. The photodiode PD includes a N-type layer 9 and a P-type layer 11. The photodiode PD converts light incident thereon into an electric potential. As such, the photodiode PD is a photoactive region of the substrate 1. The gate structure 8 functions to selectively transfer the electric potential of the photodiode PD to a drain 13. The drain 13 may be an N-type doped region of the substrate 1. The drain 13 may be formed by doping during formation of the N-type layer 9.

As further shown in FIG. 1, an interlayer dielectric (ILD) 15 is formed over the substrate 1. The ILD 15 may be formed from SiO₂, for example. A contact hole is formed in the ILD 15 to expose the drain 13, and the contact hole is filled with a conductive material to create a conductive plug 17. The conductive material may be tungsten, for example.

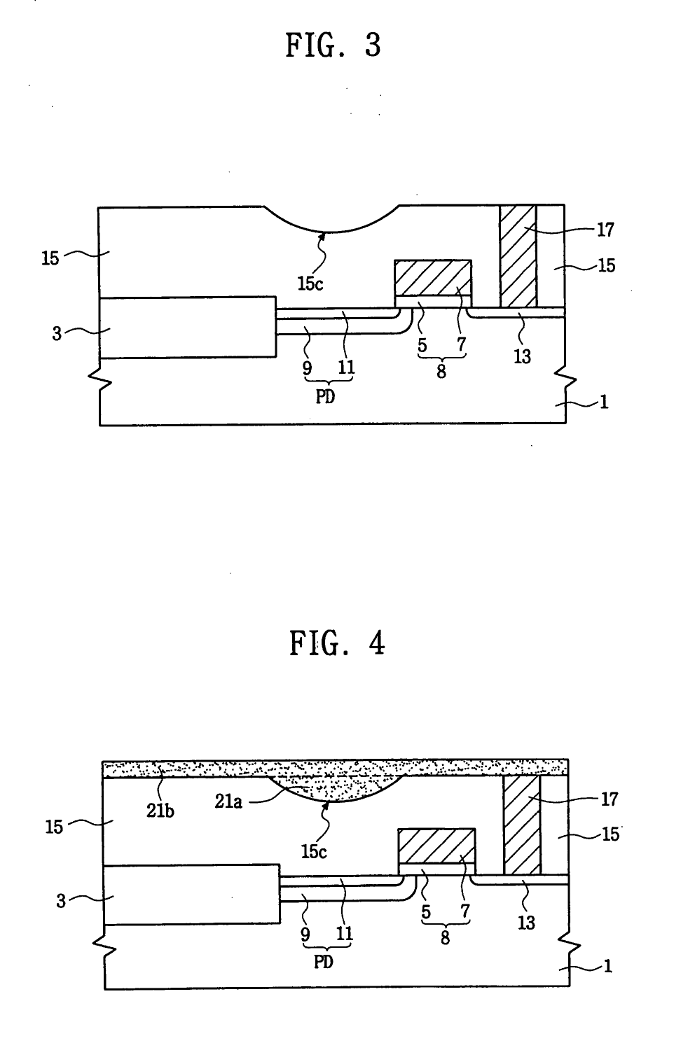

Next, as shown in FIG. 2, a photo resist pattern 19 is formed over the ILD 15 and patterned. The photo resist pattern 19 serves as an etching mask for a subsequent etching step shown in FIG. 3. In particular, the photo resist pattern 19 leaves a portion of the ILD 15 over the photodiode PD exposed.

Referring to FIG. 3, the ILD 15 is isotropically etched to form a concavity 15c in an upper surface of the ILD 15. Namely, the upper surface of the ILD 15 has a concave portion 15c over the photodiode PD. For example, the isotropic etching may be carried out by wet-etching the ILD 15 using a hydroflourine (HF) based etchant. In this example, the etchant has selectivity such that the photo resist pattern 19 is not attacked. The etch time and etch rate of the etchant may be controlled to achieve a desired radius of curvature for the concavity; and therefore, are a matter of design choice. After etching, the photo resist pattern 19 is removed.

As shown in FIG. 4, an insulating material is formed over the substrate to form an inner lens 21a and an etch stop layer 21b. The inner lens 21a fills the concavity 15c. The etch stop layer 21b covers the inner lens 21a and the ILD 15. Namely, the etch stop layer 21b extends over the ILD 15. In one embodiment the insulating material forming the inner lens 21a and the etch stop layer 21b may be silicon nitride (SiN). However, the lens 21a and/or etch stop layer 21b may be formed of any insulating material such that the refractive indices of the lens 21a and the etch stop layer 21b are higher than the ILD 15. Also, optionally, a planarization process may be performed to planarize the etch stop layer 21b. In one embodiment, the etch stop layer 21b has a thickness of 500 angstroms.

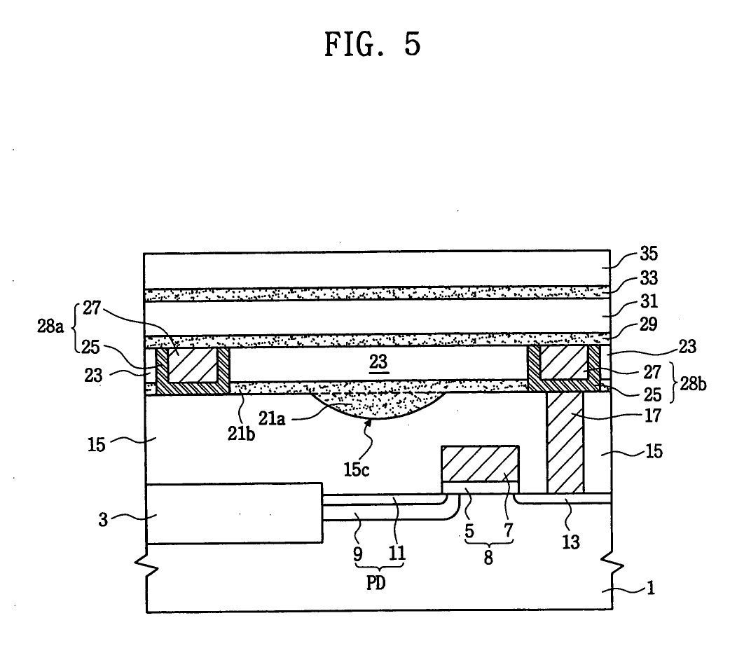

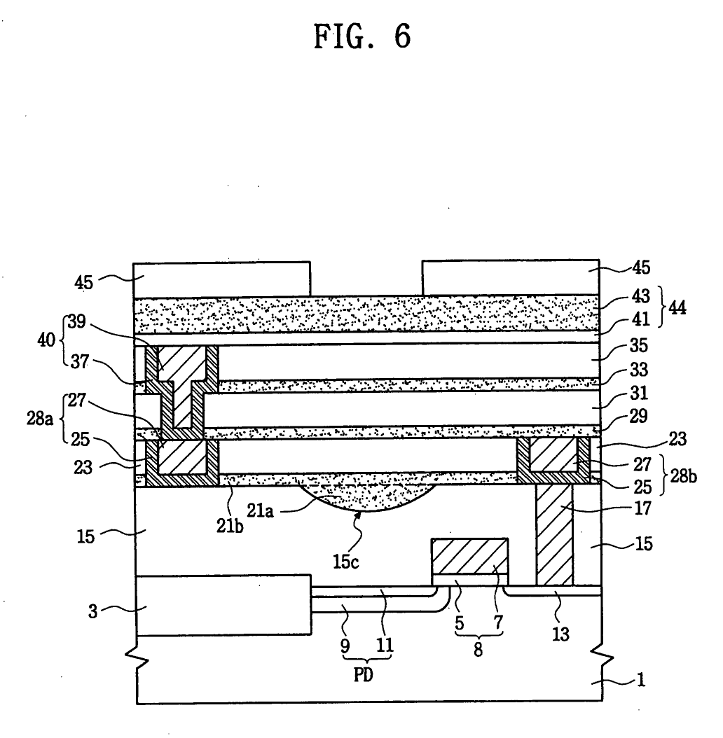

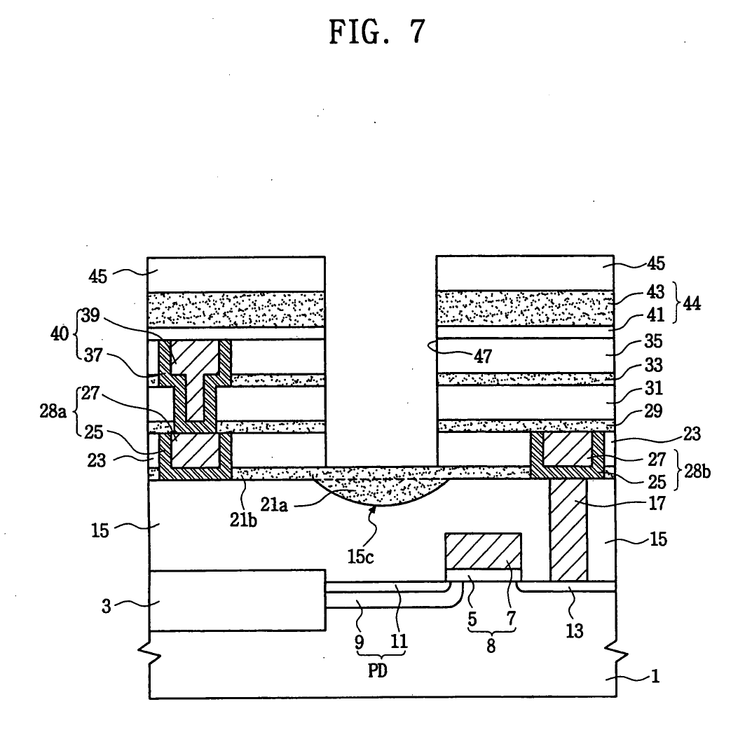

Next, as shown in FIGS. 5 and 6, a dual damascene process may be performed. Referring to FIG. 5, a first inter metal dielectric (IMD) 23 is formed over the etch stop layer 21b. A photo resist pattern (not shown) is formed over the first IMD 23 exposing portions of the first IMD 23 on either side of the inner lens 21a. One of the exposed portions is disposed over the conductive plug 17. Using the photo resist pattern as an etch mask, the first IMD 23 and the etch stop layer 21b are etched to expose the conductive plug 17 on one side of the inner lens 21a and the ILD 15 on the other side of the inner lens 21a.

A first metal interconnect 28a and a second metal interconnect 28b are formed in the vias created by the etching of the first IMD 23 and the etch stop layer 21b. The first and second metal interconnects 28a and 28b include a barrier metal layer 25 and a metal layer 27. The barrier metal layer 25 may include titanium (Ti), tantalum (Ta), etc. The metal layer 27 may include copper (Cu). By planarizing (e.g., chemical mechanical polishing), the first and second metal interconnects 28a and 28b do not extend over the first IMD 23.

Still referring to FIG. 5, a first barrier layer 29 is formed over the substrate 1 to cover the first IMD 23 and the first and second metal interconnects 28a and 28b. The first barrier layer 29 may be silicon nitride (SiN). Then, a second IMD 31 is formed over the first barrier layer 29. The second IMD 31 may be formed from the same material as the first IMD 23; for example, silicon dioxide (SiO₂), or a different material. A second barrier layer 33 and a third IMD 35 are subsequently formed. The second barrier layer 33 may be formed from the same material as the first barrier layer 29; for example, silicon nitride, or may be formed of a different material. The third IMD 35 may be formed of the same material as the first and/or second IMDs 23 and 31; for example, silicon dioxide, or may be formed of a different material.

Referring to FIG. 6, as part of the dual damascene process, a via is formed through the layers 35, 33, 31 and 29 to expose the first metal interconnect 28a and form a third metal interconnect 40 in the via. For example, the via may be formed in a same manner as the other vias described above; namely, by etching using a photo resist pattern as an etch mask. The third metal interconnect 40 includes a barrier metal layer 37 and a metal layer 39. The barrier metal layer 37 may include titanium (Ti), tantalum (Ta), etc. The metal layer 39 may include copper (Cu). By planarizing (e.g., chemical mechanical polishing), the third metal interconnect 40 does not extend over the third IMD 35.

Still referring to FIG. 6, a passivation layer 44 is formed over the substrate 1 covering the third IMD 35 and the third metal interconnect 40. The passivation layer 44 may include one or more insulation layers. In the example of FIG. 6, the passivation layer 44 includes a silicon dioxide insulation layer 41 and a silicon nitride insulation layer 43. A photo resist pattern 45 is formed over the passivation layer 44 to expose a portion of the passivation layer 44 over the photodiode PD.

As shown in FIG. 7, using the photo resist pattern 45 as an etch mask, a two stage etching process is carried out to form a cavity 47 over the inner lens 21a. The first stage involves etching using an etchant with low etch selectivity such that the layers 43, 41, 35, 33, 31 and 29 are etched. After the first barrier layer 29 has been etched, the second stage is carried out by etching using an etchant with high selectivity between the material of the first IMD 23 and the material of the etch stop layer 21b. Accordingly, the first IMD 23 is etched, but the etch stop layer 21b is not substantially etched. The resulting cavity 47 extends from the passivation layer 44 to the etch stop layer 21b. By controlling the timing of the etching with the low selectivity etchant, the layers 43, 41, 35, 33, 31 and 29 may be etched away with out completely etching away the first IMD 23.

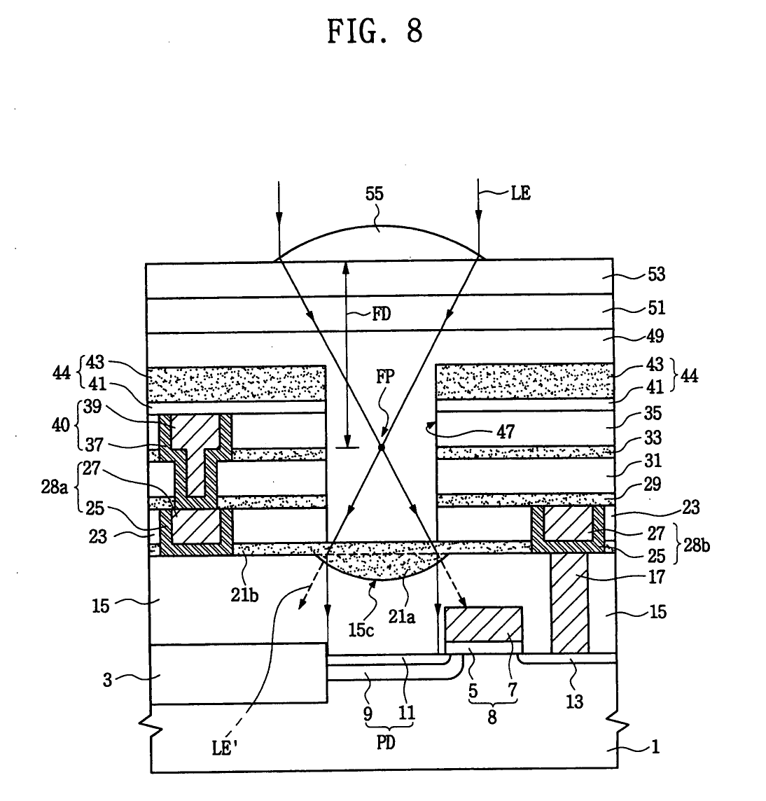

As shown in FIG. 8, a lower planarization layer 49 may then be formed in the cavity 47 and over the passivation layer 44, after removing the photo resist pattern 45. The lower planarization layer 49 may be formed of resin, and planarized through chemical mechanical polishing. A color filter layer 51, usually of resin, is formed over the low planarization layer 49. Then, an upper planarization layer 53 is formed over the color filter layer 51. The upper planarization layer 53 may be formed of resin, and planarized through chemical mechanical polishing. In one embodiment the upper and lower planarization layers 49 and 53 are formed of a same resin.

FIG. 8 further shows that a micro lens 55 may be formed on the upper planarization layer 53. The micro lens 55 may be formed according to any well-known technique and may be formed of any well-known material. As shown, the micro lens 55 serves to focus incident light rays LE on the photodiode PD. However, the focal point FP of the light rays LE, as focused by the micro lens 55, is well above the photodiode PD. As a result, absent the inner lens 21a, the light rays LE would fall on areas of the image sensor outside the intended photodiode PD as shown by the dashed lines LE′. However, the inner lens 21a serves to further direct the light rays LE to the photodiode PD and reduce and/or prevent this optical cross-talk.

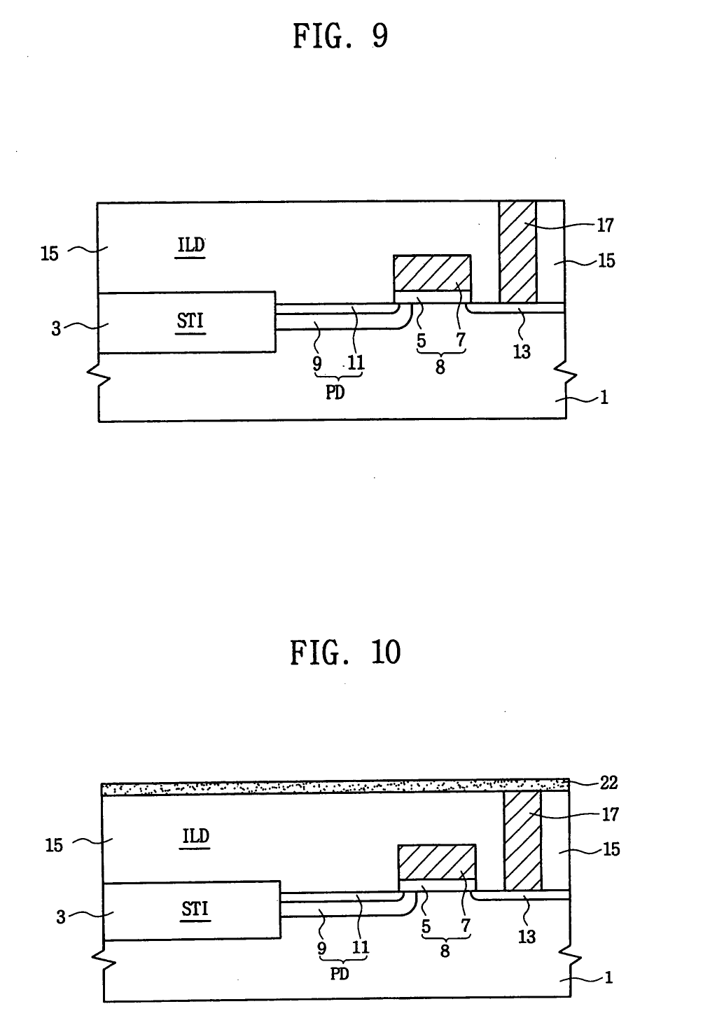

Next, a second embodiment will be described with respect to FIGS. 9-16. FIGS. 9-16 are schematic cross-sectional views of an image sensor during various stages of a fabrication process according to another embodiment of the present invention. FIG. 9 shows the same process as shown in FIG. 1, and therefore this description will not be repeated. As shown in FIG. 10, after the process of FIG. 9, a first barrier layer 22 is formed over the substrate 1 covering the ILD 15 and the conductive plug 17. The first barrier layer 22 may be formed of silicon nitride.

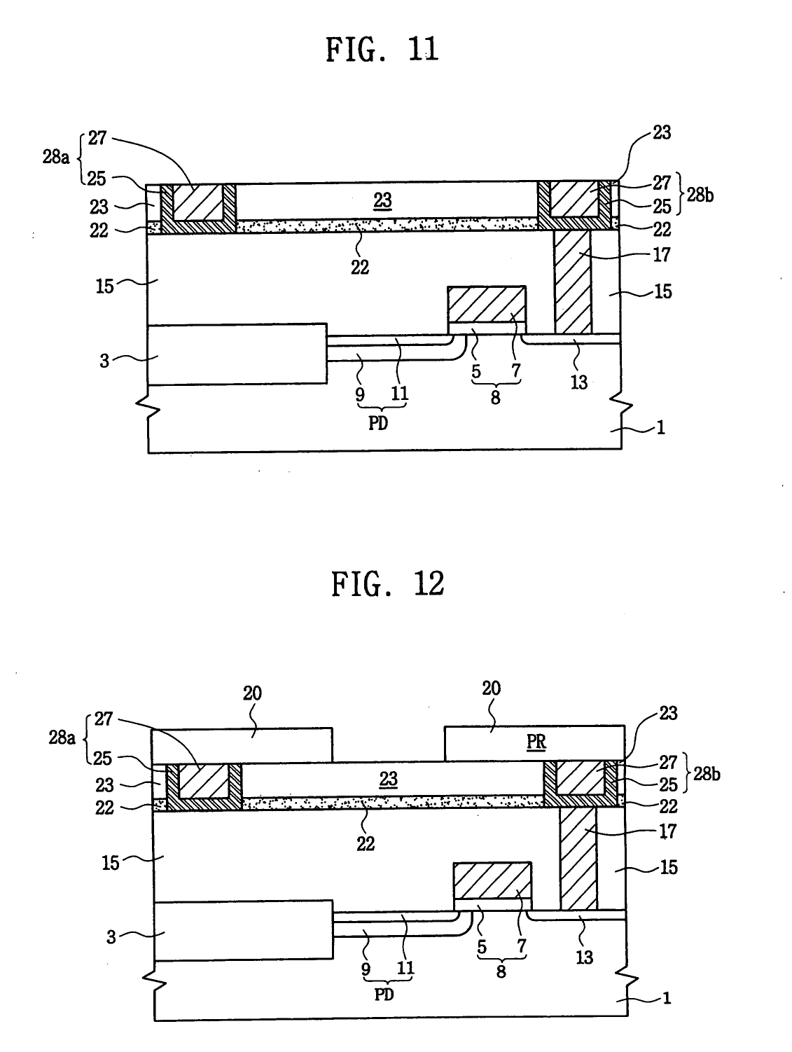

Next, as shown in FIGS. 11-15, a dual damascene process may be performed. Referring to FIG. 11, a first inter metal dielectric (IMD) 23 is formed over the barrier layer 22. A photo resist pattern (not shown) is formed over the first IMD 23 exposing portions of the first IMD 23 on either side of the photodiode PD. One of the exposed portions is disposed over the conductive plug 17. Using the photo resist pattern as an etch mask, the first IMD 23 and the first barrier layer 22 are etched to expose the conductive plug 15 on one side of the photodiode PD and the ILD 15 on the other side of the photodiode PD.

A first metal interconnect 28a and a second metal interconnect 28b are formed in the vias created by the etching of the first IMD 23 and the first barrier layer 22. The first and second metal interconnects 28a and 28b include a barrier metal layer 25 and a metal layer 27. The barrier metal layer 25 may include titanium (i), tantalum (Ta), etc. The metal layer 27 may include copper (Cu). By planarizing (e.g., chemical mechanical polishing), the first and second metal interconnects 28a and 28b do not extend over the first IMD 23.

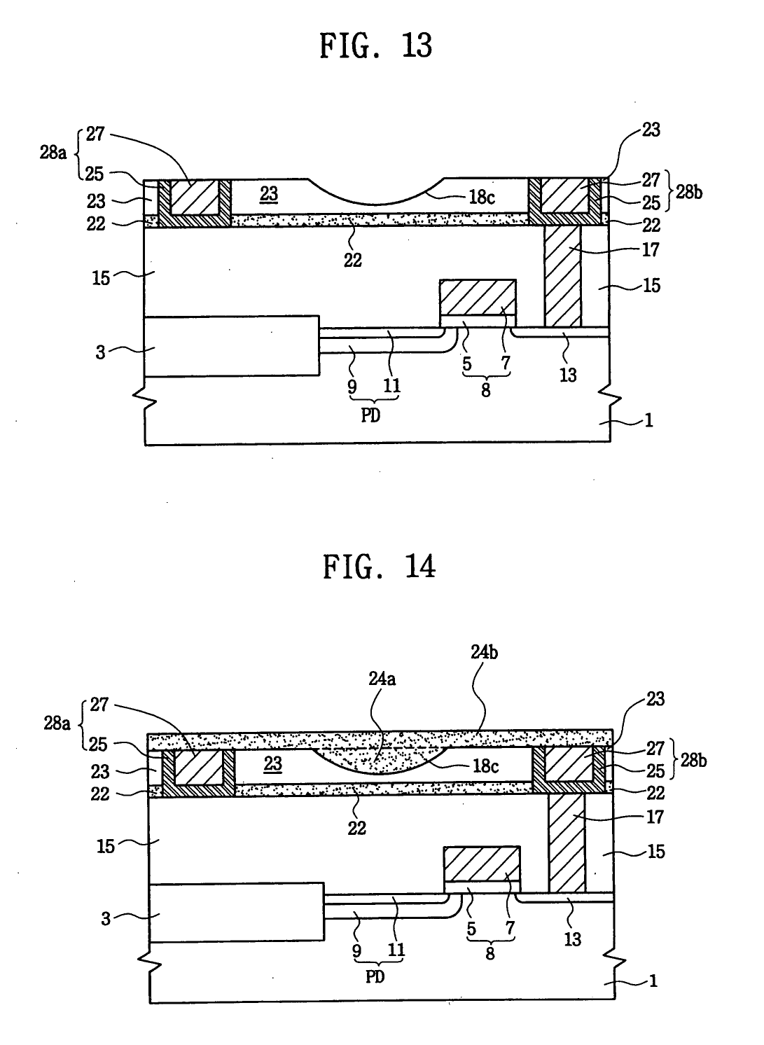

Next, as shown in FIG. 12, a photo resist pattern 20 is formed over the substrate 1 and patterned. The photo resist pattern 20 serves as an etching mask for a subsequent etching step shown in FIG. 13. In particular, the photo resist pattern 20 leaves a portion of the IMD 23 over the photodiode PD exposed.

Referring to FIG. 13, the IMD 23 is isotropically etched to form a concavity 18c in an upper surface of the IMD 23. Namely, the upper surface of the IMD 23 has a concave portion 18c over the photodiode PD. For example, the isotropic etching may be carried out by wet-etching the IMD 23 using a hydroflourine (HF) based etchant. In this example, the etchant has selectivity such that the photo resist pattern 20 is not attacked. The etch time and etch rate of the etchant may be controlled to achieve a desired radius of curvature for the concavity; and therefore, are a matter of design choice. After etching, the photo resist pattern 20 is removed.

As shown in FIG. 14, an insulating material is formed over the substrate to form an inner lens 24a and an etch stop layer 24b. The inner lens 24a fills the concavity 18c. The etch stop layer 24b covers the inner lens 24a, the IMD 23, and the first and second metal interconnects 28a and 28b. Namely, the etch stop layer 24b extends over the IMD 23. In one embodiment the insulating material forming the inner lens 24a and the etch stop layer 24b may be silicon nitride (SiN). However, the lens 24a and/or etch stop layer 24b may be formed of any insulating material such that the refractive indices of the lens 24a and the etch stop layer 24b are higher than the IMD 23. Also, optionally, a planarization process may be performed to planarize the etch stop layer 24b. In one embodiment, the etch stop layer 24b has a thickness of 500 angstroms.

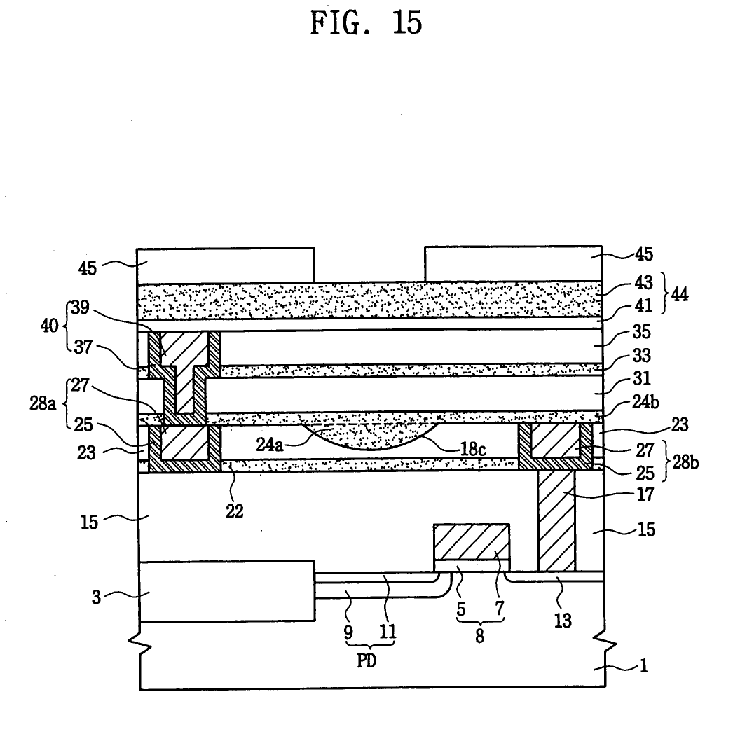

Referring to FIG. 15, a second IMD 31 is formed over the etch stop layer 24b. The second IMD 31 may be formed from the same material as the first IMD 23; for example, silicon dioxide (SiO₂), or a different material. A second barrier layer 33 and a third IMD 35 are subsequently formed. The second barrier layer 33 may be formed from the same material as the first barrier layer 22; for example, silicon nitride, or may be formed of a different material. The third IMD 35 may be formed of the same material as the first and/or second IMDs 23 and 31; for example, silicon dioxide, or may be formed of a different material.

Still referring to FIG. 15, as part of the dual damascene process, a via is formed through the layers 35, 33, 31 and 24b to expose the first metal interconnect 28a and a third metal interconnect 40 is formed in the via. For example, the via may be formed in a same manner as the other vias described above; namely, by etching using a photo resist pattern as an etch mask. The third metal interconnect 40 includes a barrier metal layer 37 and a metal layer 39. The barrier metal layer 37 may include titanium (Ti), tantalum (Ta), etc. The metal layer 39 may include copper (Cu). By planarizing (e.g., chemical mechanical polishing), the third metal interconnect 40 does not extend over the third IMD 35.

Still referring to FIG. 15, a passivation layer 44 is formed over the substrate 1 covering the third IMD 35 and the third metal interconnect 40. The passivation layer 44 may include one or more insulation layers. In the example of FIG. 15, the passivation layer 44 includes a silicon dioxide insulation layer 41 and a silicon nitride insulation layer 43. A photo resist pattern 45 is formed over the passivation layer 44 to expose a portion of the passivation layer 44 over the photodiode PD.

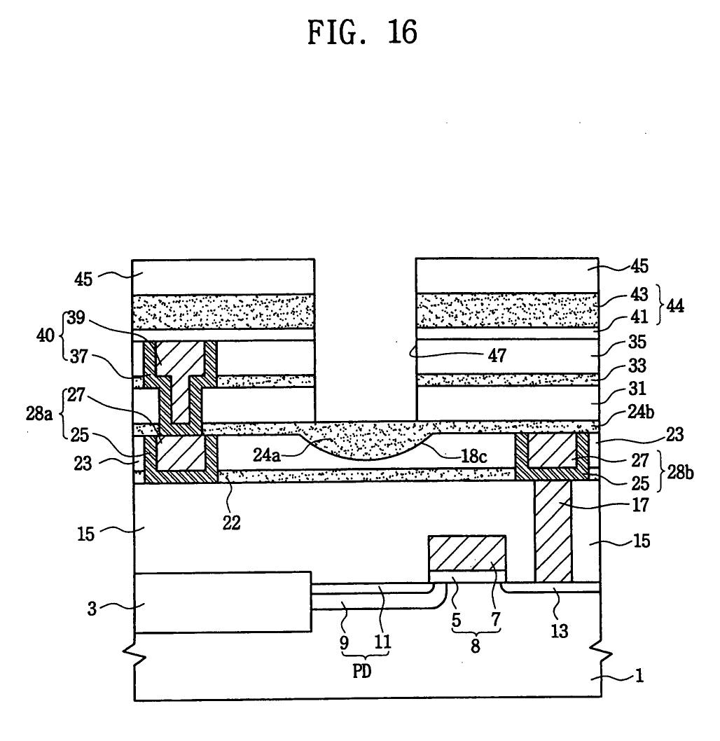

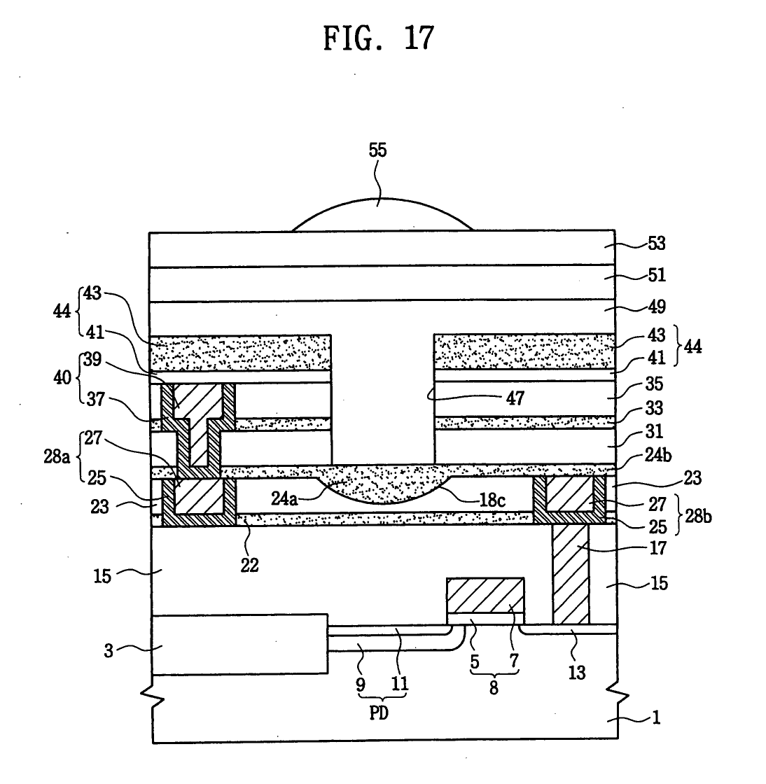

As shown in FIG. 16, using the photo resist pattern 45 as an etch mask, a two stage etching process is carried out to form a cavity 47 over the inner lens 24a. The first stage involves etching using an etchant with low etch selectivity such that the layers 43, 41, 35, and 33 are etched. After the second barrier layer 33 has been etched, the second stage is carried out by etching using an etchant with high selectivity between the material of the second IMD 31 and the material of the etch stop layer 24b. Accordingly, the second IMD 31 is etched, but the etch stop layer 24b is not substantially etched. The resulting cavity 47 extends from the passivation layer 44 to the etch stop layer 24b. By controlling the timing of the etching with the low selectivity etchant, the layers 43, 41, 35, and 33 may be etched away with out completely etching away the second IMD 31.

As shown in FIG. 17, a lower planarization layer 49 may then be formed in the cavity 47 and over the passivation layer 44, after removing the photo resist pattern 45. The lower planarization layer 49 may be formed of resin, and planarized through chemical mechanical polishing. A color filter layer 51, usually of resin, is formed over the low planarization layer 49. Then, an upper planarization layer 53 is formed over the color filter layer 51. The upper planarization layer 53 may be formed of resin, and planarized through chemical mechanical polishing. In one embodiment the upper and lower planarization layers 49 and 53 are formed of a same resin.

FIG. 17 further shows that a micro lens 55 may be formed on the upper planarization layer 53. The micro lens 55 may be formed according to any well-known technique and may be formed of any well-known material. As will be appreciated, this embodiment achieves similar advantages to those described above with respect to the first embodiment.

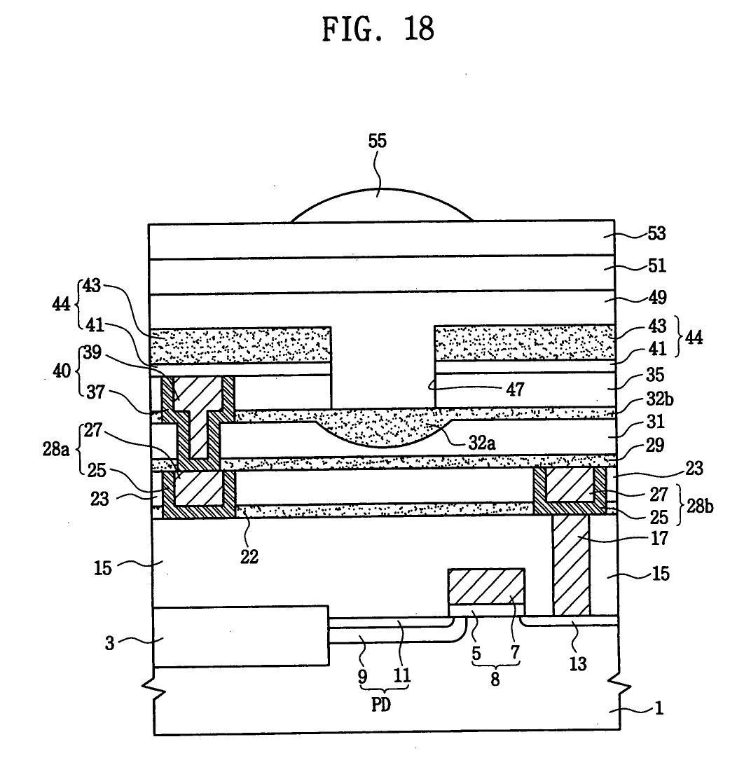

It will be appreciated from the above described embodiments, that the inner lens is not limited to being formed in the ILD 15 or the first IMD 23. Instead, the inner lens may be formed in other layers. As yet another example, FIG. 18 shows an inner lens 32a formed in the second IMD 31. Because the process steps for forming the inner lens 32a and an etch stop layer 32b in the second IMD 31 are readily apparent from the descriptions of the first and second embodiment, a detailed description of these process steps will be omitted for the sake of brevity.

The invention being thus described, it will be obvious that the same may be varied in many ways. Such variations are not to be regarded as a departure from the invention, and all such modifications are intended to be included within the scope of the invention.

I claim:

1. A method of forming an image sensor, comprising:
forming a first dielectric layer over a substrate;
removing a portion of the first dielectric layer over a photoactive region of the substrate to form a concavity in the first dielectric layer;
forming an inner lens and etch stop layer over the substrate simultaneously, the inner lens filling the concavity in the first dielectric layer, and the etch stop layer covering the inner lens and extending over the first dielectric layer;
forming a second dielectric layer over the inner lens and the etch stop layer, the second dielectric layer formed of a different material than the etch stop layer; and
forming a cavity in the second dielectric layer over the inner lens.

2. The method of claim 1, wherein the forming a cavity step includes etching using an etchant that has etch selectivity between the second dielectric layer and the etch stop layer.

3. The method of claim 1, further comprising:
forming a planarization layer over the substrate that fills the cavity; and
forming a micro lens over the planarization layer and the cavity.

4. The method of claim 1, wherein the inner lens and the etch stop layer are formed of a same material.

5. The method of claim 4, wherein the inner lens and the etch stop layer are formed of SiN.

6. The method of claim 5, wherein the second dielectric layer is SiO₂.

7. The method of claim 1, wherein the removing step comprises:
isotropically etching the first dielectric layer.

8. The method of claim 7, wherein the isotropically etching step uses a hydroflourine (HF) based etchant.

9. The method of claim 7, wherein the removing step further comprises:
forming an etching mask over the first dielectric layer prior to the isotropically etching step.

10. The method of clam 1, wherein the removing step comprises:
wet-etching the first dielectric layer.

11. The method of claim 10, wherein the wet-etching step uses an hydroflourine (HF) based etchant.

12. The method of claim 10, wherein the removing step comprises:
forming an etching mask over the first dielectric layer prior to the wet-etching step.

13. The method of claim 1, wherein the forming a second dielectric step is performed as part of a damascene process to form a metal interconnect.

14. The method of claim 13, wherein the metal interconnect includes copper.

15. The method of claim 1, wherein the forming a first dielectric layer forms the first dielectric layer directly on the photoactive region.

16. The method of claim 1, wherein the forming a first dielectric layer is performed as part of a damascene process to form a metal interconnect.

17. The method of claim 16, wherein the metal interconnect includes copper.

18. The method of claim 1, wherein the inner lens has a higher refractive index than the first dielectric layer.

19. A method of forming an image sensor, comprising:
forming an interlayer dielectric layer over a substrate such that the interlayer dielectric layer is formed over a photoactive region of the substrate;
forming an etch mask over the interlayer dielectric layer that exposes a portion of the interlayer dielectric over the photoactive region;
isotropically etching the interlayer dielectric layer using the etch mask;
removing the etch mask;
forming an inner lens and etch stop layer over the substrate simultaneously, the inner lens filling a concavity in the interlayer dielectric layer created by the isotropically etching step, and the etch stop layer covering the inner lens and extending over the interlayer dielectric layer;
performing a first damascene process to form a metal interconnect over the substrate, the first damascene process forming an inter-metal dielectric layer over the inner lens and the etch stop layer, the inter-metal dielectric layer formed of a different material than the etch stop layer;
forming a cavity in the inter-metal dielectric layer over the inner lens by etching using an etchant that has etch selectivity between the inter-metal dielectric layer and the etch stop layer;
forming a planarization layer over the substrate that fills the cavity; and
forming a micro lens over the planarization layer and the cavity.

20. The method of claim 19, wherein the inner lens and the etch stop layer are formed of a same material.

21. The method of claim 19, wherein the isotropically etching step uses a hydroflourine (HF) based etchant.

22. The method of claim 19, wherein the forming an interlayer dielectric layer is performed as part of a second damascene process to form a metal interconnect.

23. The method of claim 22, wherein the metal interconnects of the first and second damascene processes include copper.

24. The method of claim 19, wherein the inner lens has a higher refractive index than the interlayer dielectric layer.

25. A method of forming an image sensor, comprising:
forming an interlayer dielectric layer over a substrate such that the interlayer dielectric is formed over a photoactive region of the substrate;
performing a damascene process to form a first metal interconnect over the substrate, the damascene process forming a first inter-metal dielectric layer over the photoactive region of the substrate; and
forming an etch mask over the first inter-metal dielectric layer that exposes a portion of the first inter-metal dielectric over the photoactive region;
isotropically etching the first inter-metal dielectric layer using the etch mask;
removing the etch mask;
forming an inner lens and etch stop layer over the substrate simultaneously, the inner lens filling a concavity in the first inter-metal dielectric layer created by the isotropically etching step, and the etch stop layer covering the inner lens and extending over the first inter-metal dielectric layer;
performing a damascene process to form a second metal interconnect over the substrate, the damascene process forming a second inter-metal dielectric layer over the inner lens and the etch stop layer, the second inter-metal dielectric layer formed of a different material than the etch stop layer and the inter-metal dielectric layer;
forming a cavity in the second inter-metal dielectric layer over the inner lens by etching using an etchant that has etch selectivity between the second inter-metal dielectric layer and the etch stop layer;
forming a planarization layer over the substrate that fills the cavity; and
forming a micro lens over the planarization layer and the cavity.

26. The method of claim 25, wherein the inner lens and the etch stop layer are formed of a same material.

27. The method of claim 25, wherein the isotropically etching step uses a hydroflourine (HF) based etchant.

28. The method of claim 25, wherein the first and second metal interconnects include copper.

29. The method of claim 25, wherein the inner lens has a higher refractive index than the first inter-metal dielectric layer.

30. An image sensor, comprising:
a substrate having a photoactive region formed therein;
a dielectric layer formed over the substrate and having a concave portion in an upper surface, the concave portion disposed over the photoactive region;
an inner lens layer filling the concave portion of the dielectric layer and extending over the dielectric layer;
at least one interconnect structure including a plurality of layers formed over at least a portion of the inner lens layer extending over the dielectric layer, and at least one of the plurality of layers defining a cavity over the inner lens layer, and at least one of the plurality of layers forming a first metal interconnect;
a planarization layer formed over the substrate and filling the cavity; and
a micro lens formed over the planarization layer and over the photoactive region.

31. The image sensor of claim 30, wherein the inner lens layer is SiN.

32. The image sensor of claim 32, wherein at least one of the plurality of layers in the interconnect structure defining the cavity is SiO₂.

33. The image sensor of claim 30, wherein the dielectric layer is formed on the photoactive region of the substrate.

34. The image sensor of claim 30, wherein the dielectric layer is part of another interconnect structure that includes a second metal interconnect.

35. The image sensor of claim 34, wherein the second metal interconnect includes copper.

36. The image sensor of claim 34, wherein the first and second metal interconnects include copper.

37. The image sensor of claim 30, wherein the first metal interconnect includes copper.

38. The image sensor of claim 30, wherein the inner lens layer has a higher refractive index than the dielectric layer.
